(19) United States
(12) Patent Application Publication
(10) Pub. No.: US 2024/0196704 A1
(43) Pub. Date: Jun. 13, 2024

(54) COVER WINDOW AND DISPLAY DEVICE INCLUDING THE SAME

(71) Applicant: Samsung Display Co., LTD., Yongin-si (KR)

(72) Inventors: DONGJIN PARK, Yongin-si (KR); YOUNGSU KIM, Yongin-si (KR); CHEULJIN PARK, Yongin-si (KR); KISANG YOO, Yongin-si (KR); SUNGKOOK LEE, Yongin-si (KR)

(21) Appl. No.: 18/516,043

(22) Filed: Nov. 21, 2023

(30) Foreign Application Priority Data
Dec. 7, 2022 (KR) 10-2022-0169344
Mar. 29, 2023 (KR) 10-2023-0041482

(51) Int. Cl. H10K 59/80

(52) U.S. Cl. CPC H10K 59/873

(57) ABSTRACT

A cover window includes a flat surface including a first side extending in a first direction and a second side contacting the first side and extending in a second direction different from the first direction, a first side surface contacting the first side and bent from the first side, a second side surface contacting the second side and bent from the second side, a corner curved surface disposed between the first side surface and the second side surface, a first base line defining a boundary where the first side surface and the corner curved surface contact each other, an entirety of the first base line having a curved shape, and a second base line defining a boundary where the second side surface and the corner curved surface contacting each other, an entirety of the second base line having a curved shape.

This application claims priority to Korean Patent Application No. 10-2022-0169344, filed on Dec. 7, 2022, and Korean Patent Application No. 10-2023-0041482, filed on Mar. 29, 2023, and all the benefits accruing therefrom under 35 U.S.C. § 119, the content of which in their entirety is herein incorporated by reference.

### BACKGROUND

### 1. Field

Embodiments provide generally to a cover window. More particularly, embodiments relate to a cover window and a display device including the same.

### 2. Description of the Related Art

With a development of information technology, an importance of a display device, which is a connection medium between a user and information, is being highlighted. For example, the use of display devices such as liquid crystal display device (“LCD”), organic light-emitting display device (“OLED”), plasma display device (“PDP”), quantum dot display device or the like is increasing.

The display device may include a cover window capable of transmitting light and a display panel disposed below the cover window and capable of emitting light. Conventionally, a display panel made of only a flat surface has been used, but recently, a display panel including various curved surfaces is used. Typically, the display device is manufactured by attaching the display panel to a lower part of the cover window.

### SUMMARY

The display panel may include a plurality of curved surfaces and a corner curved surface disposed between two adjacent curved surfaces (e.g., disposed adjacent to an edge of the display panel) among the plurality of curved surfaces. When the corner curved surface part of the display panel is attached to the cover window, buckling or wrinkling may occur. Accordingly, display quality of the display device may deteriorate.

Embodiments provide a cover window with improved display quality.

Embodiments provide a display device including the cover window.

A cover window in an embodiment of the disclosure includes a flat surface including a first side extending in a first direction and a second side contacting the first side and extending in a second direction different from the first direction, a first side surface contacting the first side and bent from the first side, a second side surface contacting the second side and bent from the second side, a corner curved surface disposed between the first side surface and the second side surface, a first base line defining a boundary where the first side surface and the corner curved surface contact each other, an entirety of the first base line having a curved shape, and a second base line defining a boundary where the second side surface and the corner curved surface contact each other, an entirety of the second base line having a curved shape.

In an embodiment, a length of the first base line and a length of the second base line may be equal to each other.

In an embodiment, a length of the first base line and a length of the second base line may be different from each other.

In an embodiment, each of the first base line and the second base line may have a shape of a part of a different quadratic curve.

In an embodiment, the first base line may have a shape of a part of one curve including at least one of an ellipse, a parabola, and a hyperbola and the second base line may have a shape of a part of one curved including at least one of an ellipse, a parabola, and a hyperbola.

In an embodiment, a length of the first side may be less than a length of the second side and the first base line may have a shape of a part of a circular curve, and the second base line may have a shape of a part of one curve including at least one of an ellipse, a parabola, and a hyperbola.

In an embodiment, a length of the first side may be less than a length of the second side and the first base line may have a shape of a part of one curved including at least one of an ellipse, a parabola, and a hyperbola, and the second base line may have a shape of a part of a circular curve.

In an embodiment, an angle between a tangent line of the first base line passing through a point where the flat surface and the first base line meet and the flat surface may be about 170 degrees to about 180 degrees and an angle between a tangent line of the second base line passing through a point where the flat surface and the second base line meet and the flat surface may be about 170 degrees to about 180 degrees.

In an embodiment, an angle between an extension line of the flat surface and a tangent line of the first base line at an end of the first base line spaced apart from the flat surface may be about 30 degrees to about 105 degrees and an angle between an extension line of the flat surface and a tangent line of the second base line at an end of the second base line spaced apart from the flat surface may be about 30 degrees to about 105 degrees.

A display device in an embodiment of the disclosure includes a display panel including a display area on which a plurality of pixels is disposed and a cover window disposed on the display panel. The cover window includes a flat surface including a first side extending in a first direction and a second side contacting the first side and extending in a second direction different from the first direction, a first side surface contacting the first side and bent from the first side, a second side surface contacting the second side and bent from the second side, a corner curved surface disposed between the first side surface and the second side surface, a first base line defining a boundary where the first side surface and the corner curved surface contact each other, an entirety of the first base line having a curved shape, and a second base line defining a boundary where the second side surface and the corner curved surface contact each other, an entirety of the second base line having a curved shape.

In an embodiment, a length of the first base line and a length of the second base line may be equal to each other.

In an embodiment, a length of the first base line and a length of the second base line may be different from each other.

In an embodiment, each of the first base line and the second base line may have a shape of a part of a different quadratic curve.

In an embodiment, the first base line may have a shape of a part of one curved including at least one of an ellipse, a parabola, and a hyperbola and the second base line may have a shape of a part of one curved including at least one of an ellipse, a parabola, and a hyperbola.

In an embodiment, a length of the first side may be less than a length of the second side and the first base line may have a shape of a part of a circular curved, and the second base line may have a shape of a part of one curved including at least one of an ellipse, a parabola, and a hyperbola.

In an embodiment, a length of the first side may be less than a length of the second side and the first base line may have a shape of a part of one curved including at least one of an ellipse, a parabola, and a hyperbola, and the second base line may have a shape of a part of a circular curve.

In an embodiment, an angle between a tangent line of the first base line passing through a point where the flat surface and the first base line meet and the flat surface may be about 170 degrees to about 180 degrees and an angle between a tangent line of the second base line passing through a point where the flat surface and the second base line meet and the flat surface may be about 170 degrees to about 180 degrees.

In an embodiment, an angle between an extension line of the flat surface and a tangent line of the first base line at an end of the first base line spaced apart from the flat surface may be about 30 degrees to about 105 degrees and an angle between an extension line of the flat surface and a tangent line of the second base line at an end of the second base line spaced apart from the flat surface may be about 30 degrees to about 105 degrees.

In an embodiment, the display area may include a front display area overlapping the flat surface in a plan view and including a surface which is flat, an upper display area overlapping the first side surface in the plan view and including a curved surface, and a right display area overlapping the second side surface in the plan view and including a curved surface.

In an embodiment, the display area may further include a corner display area disposed between the upper display area and the right display area, overlapping the corner curved surface in the plan view, and including a curved surface.

A cover window in an embodiment of the disclosure includes a first base line, an entirety of the first base line having a curved shape, and a second base line, an entirety of the second base line having a curved shape. Here, the first base line defines a boundary where a first side surface and a corner curved surface contact each other and the second base line defines a boundary where a second side surface and the corner curved surface contact each other. Accordingly, the surface quality and curvature quality of the corner curved surface may be improved.

In addition, buckling or wrinkling that may occur when a corner curved part of a display panel is attached to the cover window may be improved.

A cover window in another embodiment of the disclosure includes a first base line having a shape of a part of one curve including at least one of an ellipse, a parabola, and a hyperbola and a second base line having a shape of a part of one curve including at least one of an ellipse, a parabola, and a hyperbola. Here, the first base line may define a boundary where a first side surface and a corner curved surface contact each other and a second base line may define a boundary where a second side surface and the corner curved surface contact each other.

Accordingly, the curvature of each of the first base line and the second base line may vary as each of the first base line and the second base line extends. In other words, the curvature of the first base line may vary as the first base line extends, and the curvature of the second base line may vary as the second base line extends. In addition, the curvature of the corner curved surface may vary.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an embodiment of a cover window.

FIG. 2 is a plan view illustrating the cover window of FIG. 1.

FIG. 3 is an enlarged view of part ‘A’ of FIG. 1.

FIG. 4 is a diagram for explaining types of quadratic curve.

FIG. 5A is an enlarged view of part ‘B’ of FIG. 3.

FIG. 5B is an enlarged view of part ‘C’ of FIG. 3.

FIGS. 6 and 7 are enlarged views of the part ‘B’ of FIG. 3.

FIG. 8 is a perspective view illustrating an embodiment of a display device.

FIG. 9 is a diagram illustrating an embodiment of a stacked structure of the display device.

FIG. 10 is a cross-sectional view illustrating a pixel included in the display panel.

FIG. 11 is a perspective view illustrating another embodiment of the display panel included in the display device of FIG. 8.

FIG. 12 is a perspective view illustrating still another embodiment of the display panel included in the display device of FIG. 8.

### DETAILED DESCRIPTION

Hereinafter, a cover window and a display device including the same in embodiments of the disclosure will be explained in detail with reference to the accompanying drawings. The same reference numerals are used for the same components in the drawings, and redundant descriptions of the same components will be omitted.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

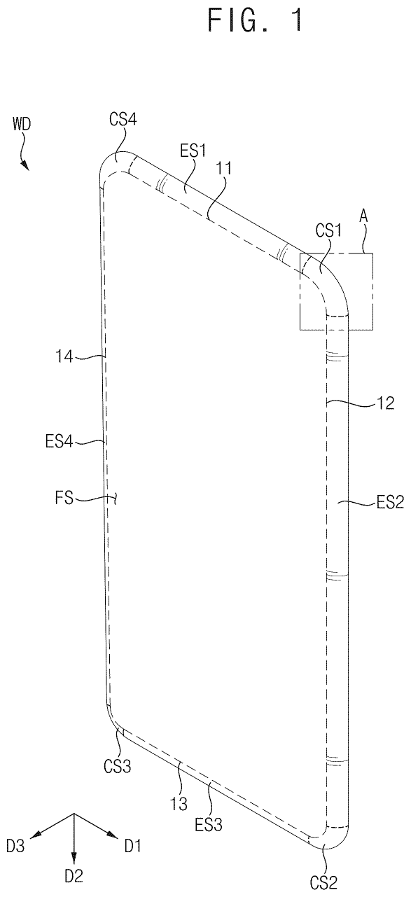

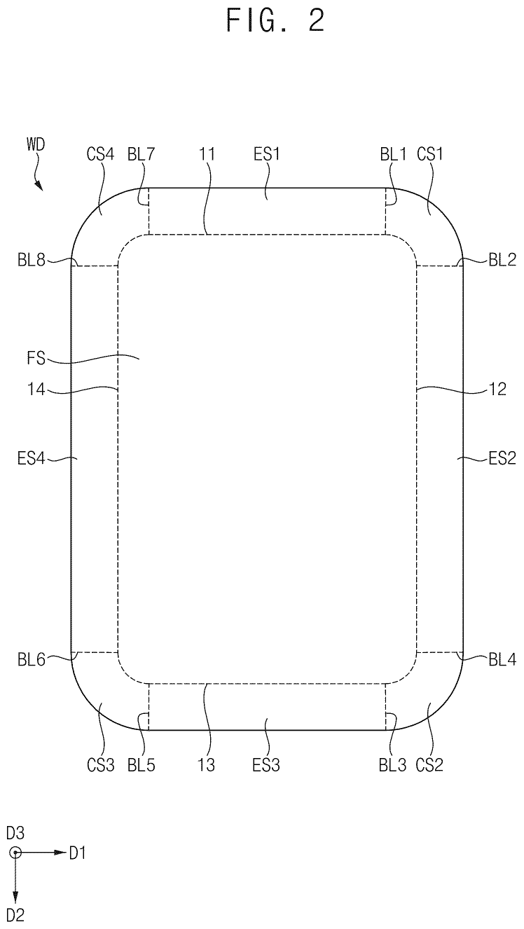

FIG. 1 is a perspective view illustrating an embodiment of a cover window. FIG. 2 is a plan view illustrating the cover window of FIG. 1.

In this specification, a plane may be defined as a first direction D1 and a second direction D2 crossing the first direction D1. In an embodiment, the first direction D1 and the second direction D2 may be perpendicular to each other, for example. A third direction D3 may indicate a normal direction of the plane, that is, a thickness direction of a cover window WD. In other words, the third direction D3 may be perpendicular to each of the first direction D1 and the second direction D2.

Referring to FIGS. 1 and 2, a cover window WD in an embodiment of the disclosure may include a flat surface FS, side surfaces ES1, ES2, ES3, and ES4, and corner curved surfaces CS1, CS2, CS3, and CS4.

The cover window WD may include transparent glass or plastic. However, the disclosure is not limited thereto, and any transparent material may be used to form the cover window WD. The cover window WD may be formed by processing plastic using an injection molding method.

In this specification, for convenience of explanation, a case in which the cover window WD includes or consists of a single layer is exemplified, but a stacked structure of the cover window WD is not limited thereto. In another embodiment, the cover window WD may include a plurality of layers.

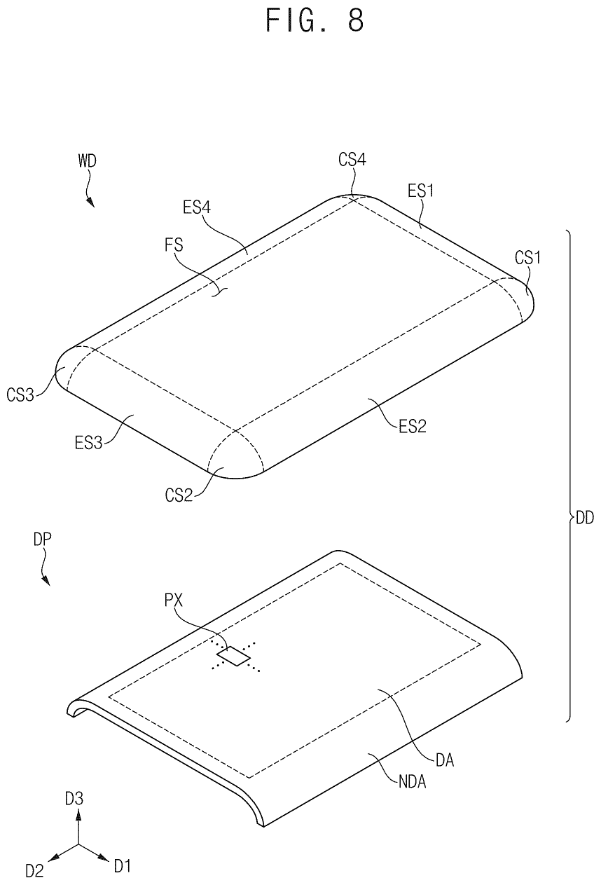

The flat surface FS may include a transparent surface which is flat. The flat surface FS may transmit an image provided by a display panel (e.g., a display panel DP of FIG. 8), which will be described later, so that a user may see the image.

The flat surface FS may include a first side 11, a second side 12, a third side 13, and a fourth side 14. In an embodiment, the flat surface FS may substantially have a quadrangular shape, e.g., rectangular shape, with rounded corners, for example. The first side 11 and the third side 13 may face each other and extend in parallel. In addition, each of the second side 12 and the fourth side 14 may be disposed between the first side 11 and the third side 13. The second side 12 and the fourth side 14 may face each other and extend in parallel.

In an embodiment, the length of the first side 11 may be less than the length of the second side 12. That is, the flat surface FS may have a quadrangular shape, e.g., rectangular shape, with rounded corners having the first side 11 as a short side and the second side 12 as a long side.

The cover window WD may include four curved surfaces respectively bent from the first side 11, the second side 12, the third side 13, and the fourth side 14 of the flat surface FS. A first side surface ES1 may be a curved surface extending from the first side 11. A second side surface ES2 may be a curved surface extending from the second side 12. A third side surface ES3 may be a curved surface extending from the third side 13. A fourth side surface ES4 may be a curved surface extending from the fourth side 14.

The first side surface ES1, the second side surface ES2, the third side surface ES3, and the fourth side surface ES4 may contact the first side 11, the second side 12, the third side 13, and the fourth side 14 of the flat surface FS respectively. In an embodiment, the first side surface ES1, the second side surface ES2, the third side surface ES3, and the fourth side surface ES4 may be unitary with each other and include or consist of the same material, for example. In this case, a boundary between the flat surface FS and the first side surface ES1, a boundary between the flat surface FS and the second side surface ES2, a boundary between the flat surface FS and the third side surface ES3, and a boundary between the flat surface FS and the fourth side surface ES4 may not be recognized.

The first side surface ES1, the second side surface ES2, the third side surface ES3, and the fourth side surface ES4 may be bent in a direction opposite to the third direction D3. That is, the first side surface ES1, the second side surface ES2, the third side surface ES3, and the fourth side surface ES4 may include bending areas that are at least partially bent. In an embodiment, the first side surface ES1, the second side surface ES2, the third side surface ES3, and the fourth side surface ES4 may be bent as a whole, for example. That is, in an embodiment, an entirety of the first side surface ES1, an entirety of the second side surface ES2, an entirety of the third side surface ES3, and an entirety of the fourth side surface ES4 may be bent without having a flat portion.

A first corner curved surface CS1 may be disposed between the first side surface ES1 and the second side surface ES2. A second corner curved surface CS2 may be disposed between the second side surface ES2 and the third side surface ES3. A third corner curved surface CS3 may be disposed between the third side surface ES3 and the fourth side surface ES4. A fourth corner curved surface CS4 may be disposed between the fourth side surface ES4 and the first side surface ES1.

That is, the first corner curved surface CS1 may connect the first side surface ES1 and the second side surface ES2. The second corner curved surface CS2 may connect the second side surface ES2 and the third side surface ES3. The third corner curved surface CS3 may connect the third side surface ES3 and the fourth side surface ES4. The fourth corner curved surface CS4 may connect the fourth side surface ES4 and the first side surface ES1.

A first base line BL1 may be defined as a boundary where the first side surface ES1 and the first corner curved surface CS1 contact each other. A second base line BL2 may be defined as a boundary where the second side surface ES2 and the first corner curved surface CS1 contact each other. A third base line BL3 may be defined as a boundary where the third side surface ES3 and the second corner curved surface CS2 contact each other. A fourth base line BL4 may be defined as a boundary where the second side surface ES2 and the second corner curved surface CS2 contact each other. A fifth base line BL5 may be defined as a boundary where the third side surface ES3 and the third corner curved surface CS3 contact each other. A sixth base line BL6 may be defined as a boundary where the fourth side surface ES4 and the third corner curved surface CS3 contact each other. A seventh base line BL7 may be defined as a boundary where the first side surface ES1 and the fourth corner curved surface CS4 contact each other. An eighth base line BL8 may be defined as a boundary where the fourth side surface ES4 and the fourth corner curved surface CS4 contact each other.

The first corner curved surface CS1 may be unitary with the first side surface ES1 and the second side surface ES2. In this case, the first base line BL1 and the second base line BL2 may not be recognized. The second corner curved surface CS2 may be unitary with the second side surface ES2 and the third side surface ES3. In this case, the third base line BL3 and the fourth base line BL4 may not be recognized. The third corner curved surface CS3 may be unitary with the third side surface ES3 and the fourth side surface ES4. In this case, the fifth base line BL5 and the sixth base line BL6 may not be recognized. The fourth corner curved surface CS4 may be unitary with the fourth side surface ES4 and the first side surface ES1. In this case, the seventh base line BL7 and the eighth base line BL8 may not be recognized.

The first side 11 and the third side 13 may correspond to each other. And the first side surface ES1 and the third side surface ES3 may correspond to each other. Similarly, the second side 12 and the fourth side 14 may correspond to each other. And the second side surface ES2 and the fourth side surface ES4 may correspond to each other. Therefore, hereinafter, the first side surface ES1 and the second side surface ES2 will be mainly described. A description of the third side surface ES3 may be substituted for a description of the first side surface ES1. In addition, a description of the fourth side surface ES4 may be substituted for a description of the second side surface ES2.

Each of the first corner curved surface CS1, the second corner curved surface CS2, the third corner curved surface CS3, and the fourth corner curved surface CS4 may have substantially the same or symmetric shapes. Therefore, hereinafter, the first corner curved surface CS1 will be mainly described. Descriptions of the second corner curved surface CS2, the third corner curved surface CS3, and the fourth corner curved surface CS4 may be substituted for a description of the first corner curved surface CS1.

The first base line BL1 may correspond to each of the third base line BL3, the fifth base line BL5, and the seventh base line BL7. The second base line BL2 may correspond to each of the fourth base line BL4, the sixth base line BL6, and the eighth base line BL8. Therefore, hereinafter, the first base line BL1 and the second base line BL2 will be mainly described. Descriptions of the third base line BL3, the fifth base line BL5, and the seventh base line BL7 may be substituted for a description of the first base line BL1. Also, descriptions of the fourth base line BL4, the sixth base line BL6, and the eighth base line BL8 may be substituted for a description of the second base line BL2.

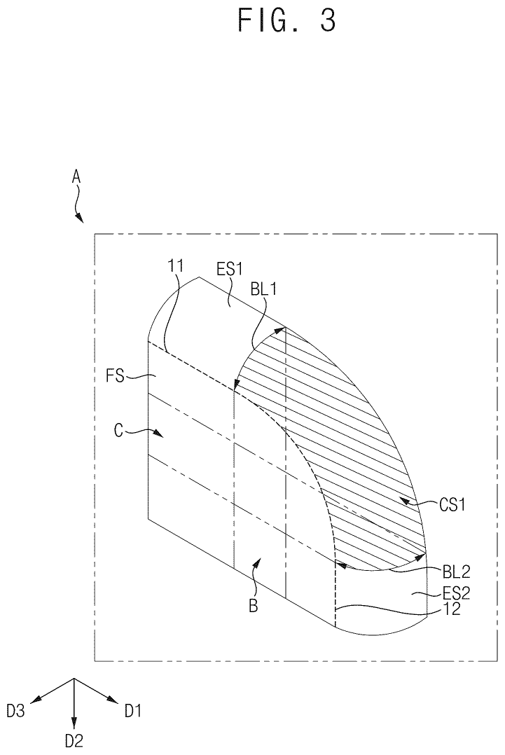

FIG. 3 is an enlarged view of part ‘A’ of FIG. 1.

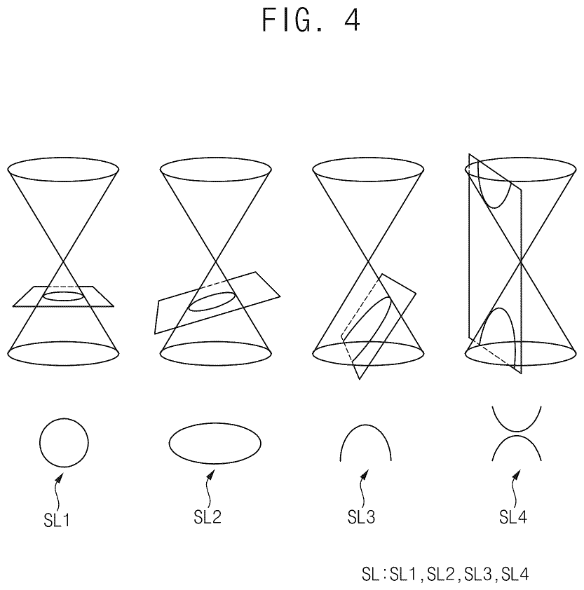

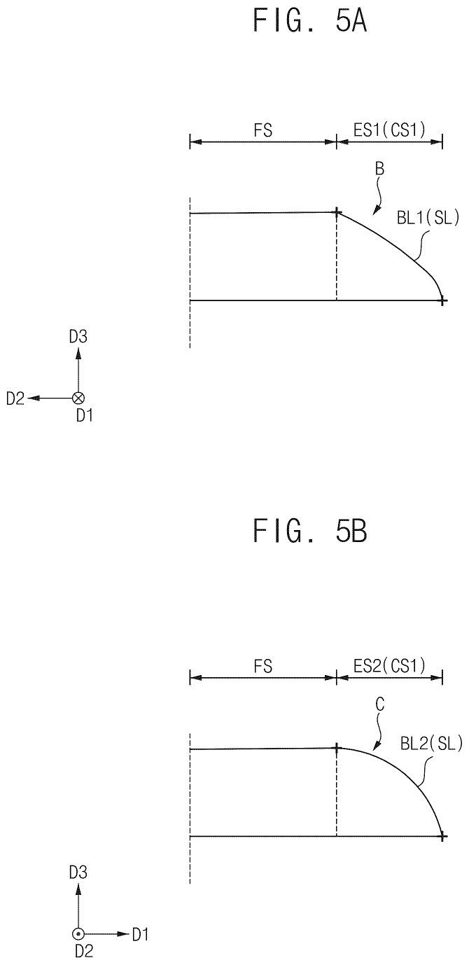

Referring to FIG. 3, the first side surface ES1 may be bent in a direction opposite to the third direction D3 from the first side 11. As described later in FIGS. 4 and 5, e.g., the first base line BL1 may substantially have a shape of a part of a circular curve. In this case, the curvature of the first side surface ES1 may be constant. In another embodiment the first base line BL1 may substantially have a shape of a part of a curve including at least one of an ellipse, a parabola, and a hyperbola. In this case, the curvature of the first side surface ES1 may vary along the third direction D3.

The second side surface ES2 may be bent in a direction opposite to the third direction D3 from the second side 12. Similarly, e.g., the second base line BL2 may substantially have a shape of a part of the circular curve. In this case, the curvature of the second side surface ES2 may be constant. In another embodiment the second base line BL2 may substantially have a shape of a part of a curve including at least one of an ellipse, a parabola, and a hyperbola. In this case, the curvature of the second side surface ES2 may vary along the third direction D3.

The first corner curved surface CS1 may be disposed between the first side surface ES1 and the second side surface ES2. In an embodiment, the first corner curved surface CS1 may have multiple curvatures (i.e., double curvatures), for example.

The first base line BL1 may be defined as a boundary where the first side surface ES1 and the first corner curved surface CS1 contact each other. The second base line BL2 may be defined as a boundary where the second side surface ES2 and the first corner curved surface CS1 contact each other. In an embodiment, the length of the first base line BL1 and the length of the second base line BL2 may be equal to each other. In another embodiment, the length of the first base line BL1 and the length of the second base line BL2 may be different from each other.

When a corner curved part of a display panel (e.g., a display panel DP of FIG. 8) is attached to a cover window (e.g., a cover window WD of FIG. 8), buckling or wrinkling may occur. Accordingly, display quality of a display device may deteriorate.

In the disclosure, in order to compensate for this, each of the first base line BL1 and the second base line BL2 may substantially have a curved shape as a whole. That is, in an embodiment, each of an entirety of the first base line BL1 and an entirety of the second base line BL2 may substantially have a curved shape without having a line shape. Accordingly, the first corner curved surface CS1 may be formed as one curved surface. Also, the curvature of the first corner curved surface CS1 may be relatively uniform. As a result, the surface quality and curvature quality of the first corner curved surface CS1 may be improved.

In addition, according to the disclosure, since each of the first base line BL1 and the second base line BL2 may substantially have a curved shape as a whole, when the display panel is attached to the cover window, the pressure applied to the display panel may be dispersed. Accordingly, buckling or wrinkling that may occur when the corner curved part of the display panel is attached to the cover window may be improved.

FIG. 4 is a diagram for explaining types of quadratic curve. FIG. 5A is an enlarged view of part ‘B’ of FIG. 3. In an embodiment, the part ‘B’ is a part cut along the first base line BL1 in the part ‘A’ of the cover window of FIG. 3 in the second direction D2, for example. FIG. 5B is an enlarged view of part ‘C’ of FIG. 3. In an embodiment, the part ‘C’ is a part cut along the second base line BL2 in the part ‘A’ of the cover window of FIG. 3 in the first direction D1, for example.

Referring to FIG. 4, in an embodiment, the first base line BL1 and the second base line BL2 may substantially have a shape of a part of different quadratic curve SL. The quadratic curve (i.e., conic section) SL may be defined as a curve obtained from a cone's surface intersecting a plane. The quadratic curve SL satisfies Equation 1 below.

ax²+bxy+cy²+dx+ey+f=0 [Equation 1]

Here, at least one of a, b, and c has a value other than zero. In an embodiment, the quadratic curve SL includes a circular curve SL1, an ellipse SL2, a parabola SL3, or a hyperbola SL4, for example.

When the quadratic curve SL is configured as the circular curve SL1, the curvature may not vary according to the length of the quadratic curve SL. That is, the curvature according to the length of the quadratic curve SL may be constant.

When the quadratic curve SL is configured as one curved including at least one of an ellipse SL2, a parabola SL3, and a hyperbola SL4, the curvature may vary according to the length of the quadratic curve SL.

Referring further to FIGS. 5A and 5B, the flat surface FS may contact the first side surface ES1 and the first corner curved surface CS1. The first base line BL1 may define a boundary where the first side surface ES1 and the first corner curved surface CS1 contact each other. In addition, the first base line BL1 may substantially have a shape of a part of the quadratic curve SL. Also, the flat surface FS may contact the second side surface ES2 and the first corner curved surface CS1. The second base line BL2 may define a boundary where the second side surface ES2 and the first corner curved surface CS1 contact each other. In addition, the second base line BL2 may substantially have a shape of a part of the quadratic curve SL.

In an embodiment, each of the first base line BL1 and the second base line BL2 may substantially have a shape of a part of the quadratic curve SL including at least one of an ellipse SL2, a parabola SL3, and a hyperbola SL4. That is, the curvature of each of the first and the second base lines BL1 and BL2 may vary as each of the first and the second base lines BL1 and BL2 extends, for example. Accordingly, the curvature of each of the first side surface ES1, the first corner curved surface CS1, and the second side surface ES2 may vary along the third direction D3.

In another embodiment the length of the first side (e.g., the first side 11 of FIG. 3) may be less than the length of the second side (e.g., the second side 12 of FIG. 3). In this case, the first base line BL1 may substantially have a shape of a part of the circular curve SL1, and the second base line BL2 may substantially have a shape of a part of the quadratic curve SL including at least one of an ellipse SL2, a parabola SL3, and a hyperbola SL4. That is, the curvature of the first base line BL1 may be constant as the first base line BL1 extends and the curvature of the second base line BL2 may vary as the second base line BL2 extends. Accordingly, the curvature of the first side surface ES1 may be constant along the third direction D3. Conversely, the curvature of each of the first corner curved surface CS1 and the second side surface ES2 may vary along the third direction D3.

In another embodiment, the length of the first side may be less than the length of the second side. In this case, the first base line BL1 may substantially have a shape of a part of the quadratic curve SL including at least one of an ellipse SL2, a parabola SL3, and a hyperbola SL4 and the second base line BL2 may substantially have a shape of a part of the circular curve SL1. That is, the curvature of the first base line BL1 may vary as the first base line BL1 extends and the curvature of the second base line BL2 may be constant as the second base line BL2 extends. Accordingly, the curvature of the second side surface ES2 may be constant along the third direction D3. Conversely, the curvature of the first corner curved surface CS1 and the first side surface ES1 may vary along the third direction D3.

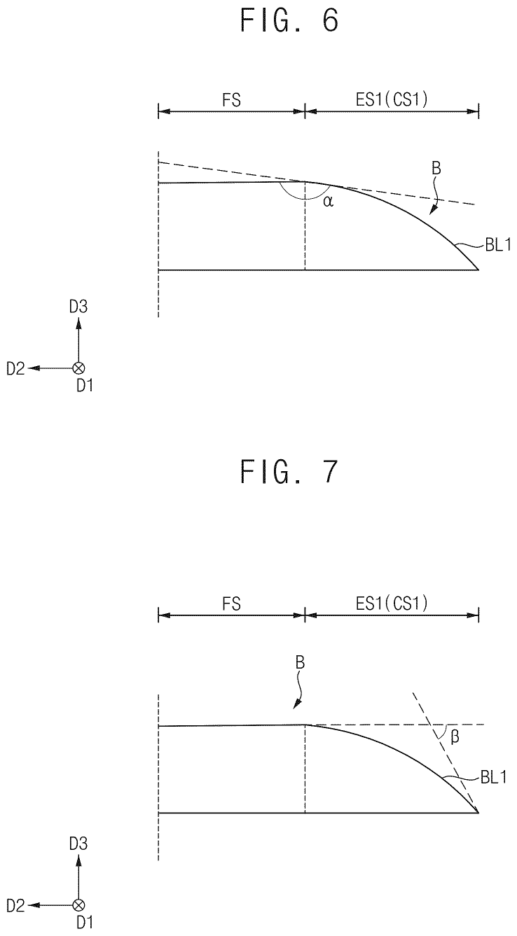

FIG. 6 is an enlarged view of the part ‘B’ of FIG. 3. In an embodiment, the part ‘B’ is a part cut along the first base line BL1 in the part ‘A’ of the cover window of FIG. 3 in the second direction D2, for example.

Referring to FIG. 6, the flat surface FS may contact the first side surface ES1 and the first corner curved surface CS1. The first base line BL1 may define a boundary where the first side surface ES1 and the first corner curved surface CS1 contact each other. And the first base line BL1 may substantially have a curved shape as a whole. In an embodiment, an angle α between a tangent line of the first base line BL1 passing through a point where the flat surface FS and the first base line BL1 meet and the flat surface FS may be about 170 degrees to about 180 degrees.

Similarly, in an embodiment, an angle between a tangent line of the second base line BL2 passing through a point where the flat surface FS and the second base line BL2 meet and the flat surface FS may be about 170 degrees to about 180 degrees.

FIG. 7 is an enlarged view of the part ‘B’ of FIG. 3. In an embodiment, the part ‘B’ is a part cut along the first base line BL1 in the part ‘A’ of the cover window of FIG. 3 in the second direction D2, for example.

Referring to FIG. 7, the flat surface FS may contact the first side surface ES1 and the first corner curved surface CS1. The first base line BL1 may define a boundary where the first side surface ES1 and the first corner curved surface CS1 contact each other. And the first base line BL1 may substantially have a curved shape as a whole. In an embodiment, an angle β between an extension line of the flat surface FS and a tangent line of the first base line BL1 at an end of the first base line BL1 spaced apart from the flat surface FS is about 30 degrees to about 105 degrees.

Similarly, in an embodiment, an angle between an extension line of the flat surface FS and a tangent line of the second base line BL2 at an end of the second base line BL2 spaced apart from the flat surface FS is about 30 degrees to about 105 degrees.

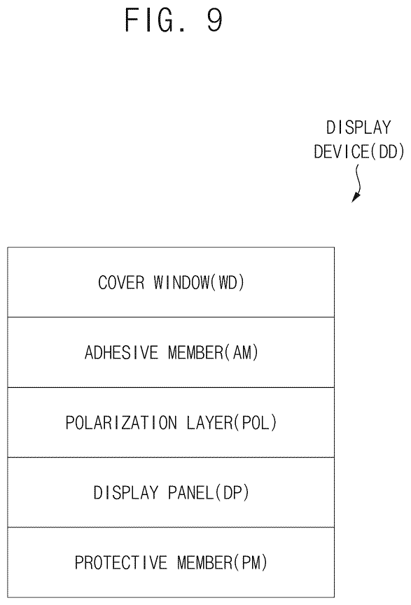

FIG. 8 is a perspective view illustrating an embodiment of a display device. FIG. 9 is a diagram illustrating an embodiment of a stacked structure of the display device. Hereinafter, descriptions overlapping with descriptions of the cover window WD described with reference to FIGS. 1, 2, and 3 will be omitted or simplified.

Referring to FIGS. 8 and 9, a display device DD in an embodiment of the disclosure may include the cover window WD, an adhesive member AM, a polarization layer POL, a display panel DP, and a protective member PM.

The cover window WD may transmit light emitted from the display panel DP. The cover window WD may include transparent glass or plastic. However, the disclosure is not limited thereto, and any transparent material may be used to form the cover window WD. The cover window WD may be attached to the polarization layer POL or the display panel DP by the adhesive member AM. The cover window WD illustrated in FIG. 8 may correspond to the cover window WD illustrated in FIGS. 1, 2, 3, 5, 6, and 7.

The adhesive member AM may be a transparent adhesive such as a pressure sensitive adhesive film (“PSA film”), an optically clear adhesive film (“OCA film”), or an optically clear resin (“OCR”). The adhesive member AM may be disposed under the cover window WD to provide adhesive force to the cover window WD. That is, the adhesive member AM may have double-sided adhesive property. In other words, the adhesive member AM may attach and fix structures disposed above the adhesive member AM and below the adhesive member AM.

External light may be incident to the display device DD. The external light may be reflected from various electrodes or lines included in the display panel DP. The polarization layer POL may prevent external light from being recognized as the external light is reflected. The polarization layer POL may be disposed under the adhesive member AM. The polarization layer POL may be omitted, and in this case, the cover window WD may be attached to the display panel DP by the adhesive member AM.

The display panel DP may be disposed under the polarization layer POL. The display panel DP may include a display area DA and a non-display area NDA. The display area DA may be an area capable of displaying an image by emitting light. A plurality of pixels PX may be disposed in the display area DA. Each of the pixels PX may emit light. The non-display area NDA may be an area that does not emit light, and may include a driving circuit for driving the pixels PX.

The protective member PM may be disposed below the display panel DP. The protective member PM may protect a lower surface of the display panel DP. The protective member PM may include a material with relatively high rigidity. In an embodiment, the protective member PM may include at least one of glass, plastic, metal, etc., for example. These may be used alone or in any combinations with each other. In addition, the protective member PM may consist of a single layer or multiple layers in combination with each other.

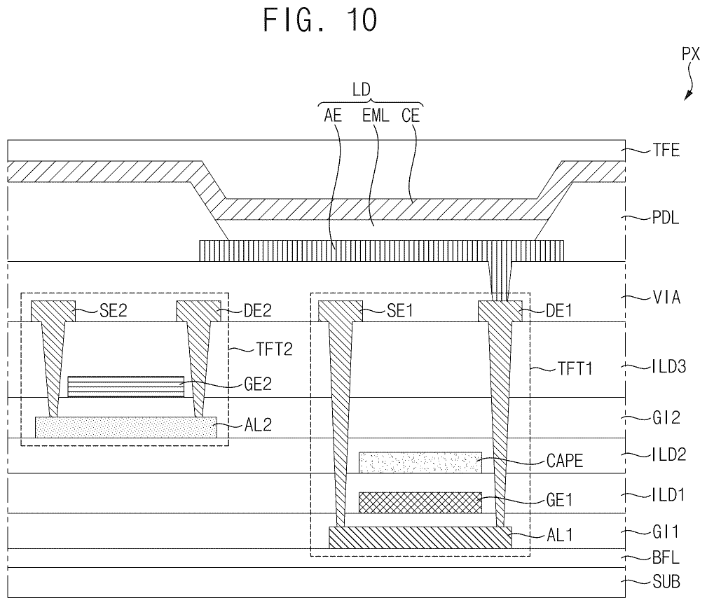

FIG. 10 is a cross-sectional view illustrating an embodiment of a pixel included in the display panel.

Referring to FIG. 10, the pixel PX may include a substrate SUB, a buffer layer BFL, a first gate insulating layer GI1, a first inter-insulating layer ILD1, a second inter-insulating layer ILD2, a second gate insulating layer GI2, a third inter-insulating layer ILD3, a via-insulating layer VIA, a pixel defining layer PDL, a first transistor TFT1, a second transistor TFT2, a light-emitting element LD, and an encapsulation layer TFE. The first transistor TFT1 may include a first active layer AL1, a first gate electrode GE1, a capacitance electrode CAPE, a first source electrode SE1, and a first drain electrode DE1. The second transistor TFT2 may include a second active layer AL2, a second gate electrode GE2, a second source electrode SE2, and a second drain electrode DE2. The light-emitting element LD may include a lower electrode AE, a light-emitting layer EML, and an upper electrode CE.

The substrate SUB may support each layer disposed on the substrate SUB. The substrate SUB may include or consist of an insulating material such as polymer resin or an inorganic material such as glass or quartz.

The buffer layer BFL may be disposed on the substrate SUB. The buffer layer BFL may prevent impurities from penetrating into the first transistor TFT1 and the second transistor TFT2. The buffer layer BFL may include at least one of silicon nitride, silicon oxide, silicon oxynitride, etc. These may be used alone or in any combinations with each other.

The first active layer AL1 may be disposed on the buffer layer BFL. The first active layer AL1 may act as a channel of the first transistor TFT1. The first active layer AL1 may include a silicon-based semiconductor material.

The first gate insulating layer GI1 may be disposed on the first active layer AL1. The first gate insulating layer GI1 may include at least one of a silicon compound, a metal oxide, etc. These may be used alone or in any combinations with each other.

The first gate electrode GE1 may be disposed on the first gate insulating layer GI1. The first gate electrode GE1 may receive a gate signal input by a driver. To this end, the first gate electrode GE1 may include at least one of a metal, an alloy, a metal nitride, a conductive metal oxide, a transparent conductive material, etc. These may be used alone or in any combinations with each other.

The first inter-insulating layer ILD1 may be disposed on the first gate electrode GE1. The first inter-insulating layer ILD1 may include at least one of a silicon compound, a metal oxide, etc. These may be used alone or in any combinations with each other.

The capacitance electrode CAPE may be disposed on the first inter-insulating layer ILD1. The capacitance electrode CAPE and the first gate electrode GE1 may constitute a capacitor.

The second inter-insulating layer ILD2 may be disposed on the capacitance electrode CAPE. The second inter-insulating layer ILD2 may include at least one of a silicon compound, a metal oxide, etc. These may be used alone or in any combinations with each other.

The second active layer AL2 may be disposed on the second inter-insulating layer ILD2. The second active layer AL2 may act as a channel of the second transistor TFT2. The second active layer AL2 may include an oxide-based semiconductor material.

The second gate insulating layer GI2 may be disposed on the second active layer AL2. The second gate insulating layer GI2 may include at least one of a silicon compound, a metal oxide, etc. These may be used alone or in any combinations with each other.

The second gate electrode GE2 may be disposed on the second gate insulating layer GI2. The second gate electrode GE2 may receive a gate signal input by the driver. To this end, the second gate electrode GE2 may include at least one of a metal, an alloy, a metal nitride, a conductive metal oxide, a transparent conductive material, etc. These may be used alone or in any combinations with each other.

The third inter-insulating layer ILD3 may be disposed on the second gate electrode GE2. The third inter-insulating layer ILD3 may include at least one of a silicon compound, a metal oxide, etc. These may be used alone or in any combinations with each other.

The first source electrode SE1, the second source electrode SE2, the first drain electrode DE1, and the second drain electrode DE2 may be disposed on the third inter-insulating layer ILD3. The first source electrode SE1 and the first drain electrode DE1 may be connected to the first active layer AL1 through a contact hole. The second source electrode SE2 and the second drain electrode DE2 may be connected to the second active layer AL2 through a contact hole. The source electrodes SE1 and SE2 and the drain electrodes DE1 and DE2 may include a conductive material including at least one of molybdenum (Mo), copper (Cu), aluminum (Al), titanium (Ti), etc. These may be used alone or in any combinations with each other.

The via-insulating layer VIA may be disposed on the source electrodes SE1 and SE2 and the drain electrodes DE1 and DE2. The via-insulating layer VIA may include an organic insulating material such as polyimide (“PI”).

The lower electrode AE may be disposed on the via-insulating layer VIA. The lower electrode AE may be connected to the first drain electrode DE1 through a contact hole. Accordingly, the lower electrode AE may be electrically connected to the first transistor TFT1. The lower electrode AE may include a conductive material including at least one of metal, alloy, transparent conductive oxide, etc. These may be used alone or in any combinations with each other. In an embodiment, the lower electrode AE may act as an anode electrode, for example.

The pixel defining layer PDL may be disposed on the via-insulating layer VIA. The pixel defining layer PDL may cover an edge of the lower electrode AE and may have an opening exposing an upper surface of the lower electrode AE. The pixel defining layer PDL may include an organic insulating material such as polyimide (“PI”).

The light-emitting layer EML may be disposed on the lower electrode AE. Specifically, the light-emitting layer EML may be disposed on the lower electrode AE exposed by the opening. The light-emitting layer EML may include at least one of an organic light-emitting material and a quantum dot.

The upper electrode CE may be disposed on the light-emitting layer EML. Also, the upper electrode CE may be disposed on the pixel defining layer PDL. The upper electrode CE may include a conductive material including at least one of metal, alloy, transparent conductive oxide, etc. These may be used alone or in any combinations with each other. In an embodiment, the conductive material may include at least one of aluminum (Al), platinum (Pt), silver (Ag), magnesium (Mg), gold (Au), chromium (Cr), tungsten (W), titanium (Ti), etc., for example. In an embodiment, the upper electrode CE may act as a cathode electrode, for example.

The encapsulation layer TFE may be disposed on the upper electrode CE. The encapsulation layer TFE may protect the light-emitting element LD, the first transistor TFT1, and the second transistor TFT2 from external moisture or dust.

Although an embodiment of the pixel PX is described with reference to FIG. 10, the pixel PX is not limited to the structure illustrated in FIG. 10. That is, the pixel PX may include any structure capable of receiving an electric signal and emitting light with a luminance corresponding to the intensity of the electric signal.

In addition, although the display device DD of the disclosure is described by limiting the organic light-emitting display device, the configuration of the disclosure is not limited thereto. In other embodiments, the display device DD may include a liquid crystal display device (“LCD”), a field emission display device (“FED”), a plasma display device (“PDP”), an electrophoretic display device (“EPD”), an inorganic light-emitting display device (“ILED”), or a quantum dot display device.

FIG. 11 is a perspective view illustrating another embodiment of a display panel included in the display device of FIG. 8.

Referring to FIG. 11, a display panel DP2 may include a display area DA capable of displaying an image. The display area DA may include a front display area DA-F, a left display area DA-L, a right display area DA-R, an upper display area DA-T, and a lower display area DA-B. The left display area DA-L, the right display area DA-R, the upper display area DA-T, and the lower display area DA-B may surround the front display area DA-F.

The front display area DA-F may include a surface which is flat. The left display area DA-L and the right display area DA-R may face each other and at least partially include a curved surface. The upper display area DA-T and the lower display area DA-B may face each other and at least partially include a curved surface.

The front display area DA-F may overlap the flat surface (e.g., the flat surface FS of FIG. 8) of the cover window (e.g., the cover window WD of FIG. 8). In this case, an image provided from the front display area DA-F may be displayed through the flat surface.

The left display area DA-L may overlap the fourth side surface (e.g., the fourth side surface ES4 of FIG. 8) of the cover window. The right display area DA-R may overlap the second side surface (e.g., the second side surface ES2 of FIG. 8) of the cover window. The upper display area DA-T may overlap the first side surface (e.g., the first side surface ES1 of FIG. 8) of the cover window. The lower display area DA-B may overlap the third side surface (e.g., the third side surface ES3 of FIG. 8) of the cover window.

In this case, an image provided from the left display area DA-L may be displayed through the fourth side surface. An image provided from the right display area DA-R may be displayed through the second side surface. An image provided from the upper display area DA-T may be displayed through the first side surface. An image provided from the lower display area DA-B may be displayed through the third side surface.

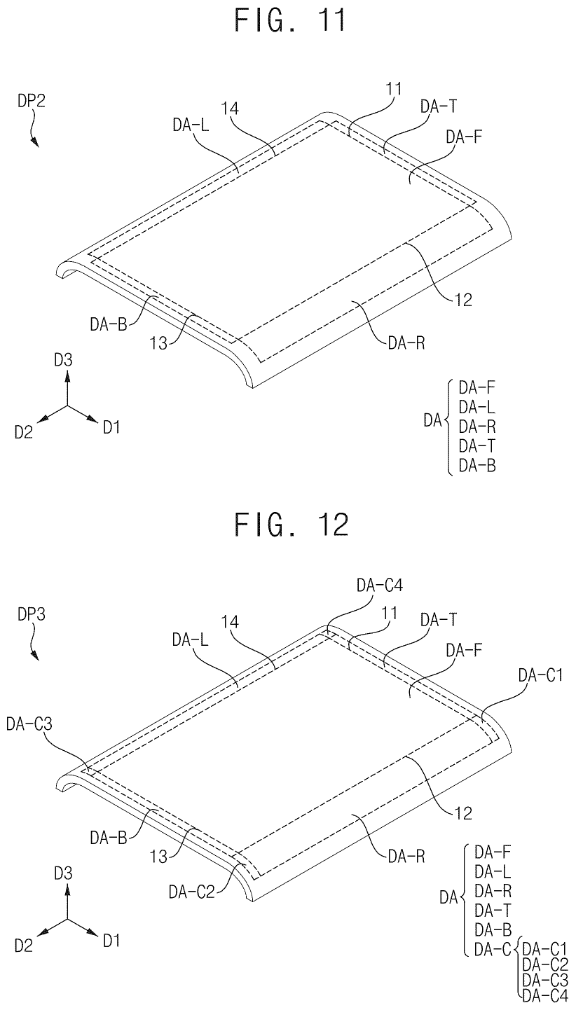

FIG. 12 is a perspective view illustrating still another embodiment of a display panel included in the display device of FIG. 8.

Referring to FIG. 12, a display panel DP3 may include a display area DA capable of displaying an image. The display area DA may include a front display area DA-F, a left display area DA-L, a right display area DA-R, an upper display area DA-T, a lower display area DA-B, and a corner display area DA-C.

The display panel DP3 may be substantially the same to the display panel DP2 described with reference to FIG. 11 except that the display area DA further includes a corner display area DA-C. Hereinafter, descriptions overlapping descriptions of the display panel DP2 described with reference to FIG. 11 will be omitted or simplified.

That is, the front display area DA-F, the left display area DA-L, the right display area DA-R, the upper display area DA-T, and the lower display area DA-B may be substantially the same to the front display area DA-F, the left display area DA-L, the right display area DA-R, the upper display area DA-T, and the lower display area DA-B described with reference to FIG. 11. Therefore, a description thereof will be omitted.

The display area DA of the display panel DP3 in another embodiment of the disclosure may further include the corner display area DA-C. The corner display area DA-C may include a first corner display area DA-C1, a second corner display area DA-C2, a third corner display area DA-C3, and a fourth corner display area DA-C4.

Each of the first corner display area DA-C1, the second corner display area DA-C2, the third corner display area DA-C3, and the fourth corner display area DA-C4 may include a curved surface. The first corner display area DA-C1 may be disposed between the upper display area DA-T and the right display area DA-R. The second corner display area DA-C2 may be disposed between the right display area DA-R and the lower display area DA-B. The third corner display area DA-C3 may be disposed between the lower display area DA-B and the left display area DA-L. The fourth corner display area DA-C4 may be disposed between the left display area DA-L and the upper display area DA-T.

The first corner display area DA-C1 may overlap the first corner curved surface (e.g., the first corner curved surface CS1 of FIG. 8) of the cover window. The second corner display area DA-C2 may overlap the second corner curved surface (e.g., the second corner curved surface CS2 of FIG. 8) of the cover window. The third corner display area DA-C3 may overlap the third corner curved surface (e.g., the third corner curved surface CS3 of FIG. 8) of the cover window. The fourth corner display area DA-C4 may overlap the fourth corner curved surface (e.g., the fourth corner curved surface CS4 of FIG. 8) of the cover window.

In this case, an image provided from the first corner display area DA-C1 may be displayed through the first corner curved surface. An image provided from the second corner display area DA-C2 may be displayed through the second corner curved surface. An image provided from the third corner display area DA-C3 may be displayed through the third corner curved surface. An image provided from the fourth corner display area DA-C4 may be displayed through the fourth corner curved surface.

As such, when the display panel includes a plurality of curved display areas, a display device having a relatively large area for displaying the image may be implemented.

The disclosure may be applied to various display devices. In an embodiment, the disclosure is applicable to various display devices such as display devices for vehicles, ships and aircraft, portable communication devices, display devices for exhibition or information transmission, medical display devices, or the like, for example.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims.

What is claimed is:

1. A cover window comprising:
a flat surface including:
a first side extending in a first direction; and
a second side contacting the first side and extending in a second direction different from the first direction;
a first side surface contacting the first side and bent from the first side;
a second side surface contacting the second side and bent from the second side;
a corner curved surface disposed between the first side surface and the second side surface;
a first base line defining a boundary where the first side surface and the corner curved surface contact each other, an entirety of the first base line having a curved shape; and
a second base line defining a boundary where the second side surface and the corner curved surface contact each other, an entirety of the second base line having a curved shape.

2. The cover window of claim 1, wherein a length of the first base line and a length of the second base line are equal to each other.

3. The cover window of claim 1, wherein a length of the first base line and a length of the second base line are different from each other.

4. The cover window of claim 1, wherein each of the first base line and the second base line has a shape of a part of a different quadratic curve.

5. The cover window of claim 4, wherein the first base line has a shape of a part of one curve including at least one of an ellipse, a parabola, and a hyperbola and
the second base line has a shape of a part of one curve including at least one of an ellipse, a parabola, and a hyperbola.

6. The cover window of claim 4, wherein a length of the first side is less than a length of the second side,
the first base line has a shape of a part of a circular curve, and
the second base line has a shape of a part of one curve including at least one of an ellipse, a parabola, and a hyperbola.

7. The cover window of claim 4, wherein a length of the first side is less than a length of the second side,
the first base line has a shape of a part of one curve including at least one of an ellipse, a parabola, and a hyperbola, and
the second base line has a shape of a part of a circular curve.

8. The cover window of claim 4, wherein an angle between a tangent line of the first base line passing through a point where the flat surface and the first base line meet and the flat surface is about 170 degrees to about 180 degrees, and
an angle between a tangent line of the second base line passing through a point where the flat surface and the second base line meet and the flat surface is about 170 degrees to about 180 degrees.

9. The cover window of claim 4, wherein an angle between an extension line of the flat surface and a tangent line of the first base line at an end of the first base line spaced apart from the flat surface is about 30 degrees to about 105 degrees, and
an angle between an extension line of the flat surface and a tangent line of the second base line at an end of the second base line spaced apart from the flat surface is about 30 degrees to about 105 degrees.

10. A display device comprising:
a display panel including a display area on which a plurality of pixels is disposed; and
a cover window disposed on the display panel, the cover window comprising:
a flat surface including a first side extending in a first direction and a second side contacting the first side and extending in a second direction different from the first direction;
a first side surface contacting the first side and bent from the first side;
a second side surface contacting the second side and bent from the second side;
a corner curved surface disposed between the first side surface and the second side surface;
a first base line defining a boundary where the first side surface and the corner curved surface contact each other, an entirety of the first base line having a curved shape; and
a second base line defining a boundary where the second side surface and the corner curved surface contact each other, an entirety of the second base line having a curved shape.

11. The display device of claim 10, wherein a length of the first base line and a length of the second base line are equal to each other.

12. The display device of claim 10, wherein a length of the first base line and a length of the second base line are different from each other.

13. The display device of claim 10, wherein each of the first base line and the second base line has a shape of a part of a different quadratic curve.

14. The display device of claim 13, wherein the first base line has a shape of a part of one curve including at least one of an ellipse, a parabola, and a hyperbola and
the second base line has a shape of a part of one curve including at least one of an ellipse, a parabola, and a hyperbola.

15. The display device of claim 13, wherein a length of the first side is less than a length of the second side,
the first base line has a shape of a part of a circular curve, and
the second base line has a shape of a part of one curve including at least one of an ellipse, a parabola, and a hyperbola.

16. The display device of claim 13, wherein a length of the first side is less than a length of the second side,
the first base line has a shape of a part of one curve including at least one of an ellipse, a parabola, and a hyperbola, and
the second base line has a shape of a part of a circular curve.

17. The display device of claim 13, wherein an angle between a tangent line of the first base line passing through a point where the flat surface and the first base line meet and the flat surface is about 170 degrees to about 180 degrees, and
an angle between a tangent line of the second base line passing through a point where the flat surface and the second base line meet and the flat surface is about 170 degrees to about 180 degrees.

18. The display device of claim 13, wherein an angle between an extension line of the flat surface and a tangent line of the first base line at an end of the first base line spaced apart from the flat surface is about 30 degrees to about 105 degrees, and
an angle between an extension line of the flat surface and a tangent line of the second base line at an end of the second base line spaced apart from the flat surface is about 30 degrees to about 105 degrees.

19. The display device of claim 10, wherein the display area includes:
a front display area overlapping the flat surface in a plan view and including a surface which is flat;
an upper display area overlapping the first side surface in the plan view and including a curved surface; and
a right display area overlapping the second side surface in the plan view and including a curved surface.

20. The display device of claim 19, wherein the display area further includes a corner display area disposed between the upper display area and the right display area, overlapping the corner curved surface in the plan view, and including a curved surface.
